(19) United States
(12) Patent Application Publication
(10) Pub. No.: US 2006/0065431 A1
(43) Pub. Date: Mar. 30, 2006

(54) Self-reflowing printed circuit board and application methods

(76) Inventor: Horacio Andres Trucco, Melville, NY (US)

Correspondence Address: Horacio Andres Trucco, 25 Nursery Road, Melville, NY, 11747-1028, US

(21) Appl. No.: 10/953,846

(22) Filed: Sep. 29, 2004

(51) Int. Cl. H05K 7/20; H05B 3/16

(52) U.S. Cl. 174/250; 174/255; 219/543

(57) ABSTRACT

A novel printed circuit board (PCB) 10 that incorporates embedded into its substrate an electric heater 14 is disclosed. This electric heater 14 becomes the only source of heat for simultaneously soldering components to pads 12. The PCB 10 is the key element that permits to create apparatuses and implement processes for soldering PCB assemblies without utilizing a reflow oven. Compared against the prior art this invention requires less manufacturing equipment, reduces the manufacturing cost, reduces manufacturing energy consumption and improves the quality and reliability of soldered PCB assemblies.

### FIELD OF INVENTION

This invention relates to a novel printed circuit board (PCB) that incorporates an embedded electric heater into its substrate. Said electric heater becomes the only source of heat that allows to attain a self-reflowing process for simultaneously soldering multiple electronic components to said PCB face.

### BACKGROUND-DESCRIPTION OF THE PRIOR ART

The manufacture of most modern electronic products require a PCB that allows to electrically interconnect a variety of electronic components and also holds them together in a relatively rigid condition. Many types of components are placed over a PCB such as; resistors, capacitors, inductors, transformers, integrated circuit (IC) packages, connectors, headers, RF shields, LEDs, switches, board interface systems, battery sockets, etc. that are electrically connected and restrained by means of soldered joints either over one side or both sides of a PCB. These joints can be attained by three methods: hand soldering, the wave soldering process and by the oven reflow soldering process.

Manufacturing electronic products utilizing PCBs requires a few sequential steps performed by different machines. For example, such steps may comprise: (1) printing the PCB with soldering paste (an operation generally performed by stencil printing equipment), (2) placing surface-mount electronic components on that PCB face (an operation performed by an automated computer-controlled “pick-and-place” machine or by any other type of component placement equipment), (3) soldering the assembly (an operation, until now, performed inside a reflow oven or by a wave soldering machine), (4) cleaning the completed assembly (an operation that may involve washing and drying) and (5) testing the assembly for proper functionality (detects components damaged during step (3) and the presence of defective soldered joints.) Rework or rejection may be required after operation (5).

Mass production almost exclusively utilizes the oven reflow soldering process to accomplish above step (3). This process exhibit inherit disadvantages that, indeed, increase the cost of the final product, generate rejects, require rework and reduce the reliability of the final product. The electronic manufacturing industry accepts these inherit drawbacks and shortcomings, and works around them, for lack of a more suitable soldering process.

The oven reflow soldering process, that is carry out inside a reflow oven, simultaneously heats up the entire assembly (meaning the PCB and all of the components been soldered to the PCB) to a temperature ranging from about 20° C. (degree Celsius) to 40° C. above the temperature at which the utilized solder alloy melts or reaches liquid us state. The melting temperature of most popular solder alloys utilized by the electronic industry ranges from 190° C. to 230° C.

The majority of consumer electronic products need to be rated, and indeed are, to operate at maximum temperatures that range from 50° C. to 90° C. Consequently, components that form part of every electronic product manufactured by reflow soldering process are required to survive temperatures, at least, 120° C. higher than the temperature level encountered during their most severe actual operation. Therefore, all electronic components must be unnecessarily temperature-overrated to tolerate or survive the soldering process. This requirement for high-temperature-exposure survival increases the cost of every component to be soldered to a PCB.

During the oven reflow soldering process, thermal shock (due to a fast heating rate) can crack certain components, in particular ceramic capacitors, increasing rejects and/or requiring costly rework. Fast heating of plastic IC packages could induce cracking when moisture absorbed inside said packages can turn into steam during a oven reflow soldering process causing the so called “pop-corn” effect that internally damage the IC package. Electrolytic capacitors are extremely sensitive to high temperature exposure. Laminated PCBs may become soft by extended exposure to heat. An increase in soldering process temperature can damage a PCB metal-plated through-holes or vias, by cracking their barrels due to differential thermal expansion between the PCB dielectric material and its barrels' plating metal. Warpage, or twisting of a PCB, increases with soldering temperature. Warpage can cause defective soldered joints because coplanarity of the mating surfaces is compromised.

Recently, electrically conductive adhesives are becoming increasingly prominent in electronics packaging applications in large part because their ability to provide electrical interconnection without the need to subject the component to the harsh high-temperature environment of a oven reflow soldering process. Heat sensitive components that could be damaged during reflow process are being electrically interconnected by conductive adhesives. This type of electrical interconnection is not as desirable as traditional soldered joints and in addition increases cost.

In conclusion, the cost of manufacturing electronic products utilizing PCBs can be reduced and the quality and reliability of said products improved, if a better soldering process could be created to replace the oven reflow

A new soldering process to be more effective than the prior art, should heat the entire PCB substrate and its soldering pads (or lands) but only heat a portion of the mating leads (or terminations) extending out from electronic component casings. Therefore, allowing said casings and its internal parts to remain relatively cold. Such a novel soldering process would permit the elimination of all the disadvantages enumerated above.

When this inventor realized the urgent and long-felt need to create means to efficiently solder electronic components to a PCB without the necessity for heating the whole PCB assembly, the objectives and purposes of this invention were inspired, leading him to the conception and the accomplishment of this invention.

### OBJECTIVES AND ADVANTAGES OF THE INVENTION

The general objective of this invention is to provide the electronic manufacturing, or electronic packaging, industry with a new, safe, reliable, speedier, useful and, above all, a more economical process and means for soldering components to a PCB.

Because this invention only heats the component's leads or terminations to be joined by solder to a PCB while the rest of said component (namely its casing or housing) remains relatively cold, utilization of this invention will help to reduce manufactured-product cost because components rated to tolerate much lower temperature exposure (than now required by the oven reflow soldering process) cost less. This invention eliminates the need to de-moisturize certain components, for example the requirement set by the Joint Electronic Devices Engineering Council (JEDEC) to bake plastic BGAs at 125° C. for 24 hours prior to reflow is eliminated.

The invention can readily be integrated into conventional automated assembly equipment increasing their yield. This invention also allows to reduce the required manufacturing floor space since the traditional reflow oven is eliminated form the assembly line. Further objectives and advantages of the invention will become apparent from a consideration of the drawings and following descriptions.

### BRIEF DESCRIPTION OF THE DRAWING FIGURES

FIG. 1 shows in both exploded and sectional views a single-sided PCB constructed according to this invention that incorporates a single electric heater embedded into its substrate. The heater is capable of generating, or transferring, relatively uniform heat across the entire face of the PCB.

FIG. 2 shows in perspective view an alternative heater layout to replace the one shown in FIG. 1 consisting of a single electric heater capable of only generating heat underneath soldering pads.

FIG. 3 shows in perspective view a second alternative heater layout consisting of a double-coplanar electric heater each capable of only generating heat underneath soldering pads at different times and at different heating rates.

FIG. 4 shows in perspective view a third alternative heater layout consisting of a single electric heater capable of generating more intense heat underneath soldering pads and less intense heat over the remainder of the PCB.

FIG. 5 shows in perspective view a fourth alternative heater layout consisting of a double-coplanar electric heater each capable of generating uniform heat across a different part of the face of the PCB at different times and at different heating rates.

FIG. 6 shows in sectional view a double-sided PCB that incorporates a single embedded electric heater. Notice that a through-hole shown in the figure does not intersect the electric heater.

FIG. 7 shows in sectional view a double-sided PCB that incorporates two separate electric heaters embedded on different planes. Notice that blind vias interconnecting different layers do not intersect the electric heaters.

FIG. 8 shows in sectional view a portion of a single-sided PCB and a component being soldered to it. The figure demonstrates why insignificant heating reaches the casing of a component being soldered, see arrows indicating heat transfer path.

FIG. 9 shows in sectional view an apparatus that represents a simple embodiment of this invention that permits to solder PCB assemblies in batch mode.

FIG. 10 compares, in a block diagram fashion, the prior art approach for oven reflow soldering PCB assemblies against a new method according to this invention. Notice the transposition between reflow and components placement steps as pointed out by arrow lines.

FIG. 11 shows a new soldering process for automated production of PCB assemblies according to the novel method presented in FIG. 10. Fundamentally, an empty PCB with single lumps of molten solder covering its soldering pads is sequentially fed into a conventional pick-and-place machine. Components are placed over and deepen into the molten solder lumps forming soldered joints.

FIG. 12 shows in perspective view an already soldered PCBwEEH assembly being repaired with the assistance of its embedded electric heater.

### REFERENCE NUMERALS IN DRAWINGS

Underlined numerals designate either an assembly or a group of parts. Notes in parentheses help to identify to which assembly the preceding part belongs, the working or function of the preceding part or the relationship of the preceding part to a method or process.

The parts cited in the following description are:
10 printed circuit board with embedded electric heater (PCBwEEH for short),
12 soldering pad (part of 10),
14 embedded electric heater (part of 10),
16 top dielectric layer (part of 10),
18 bottom dielectric layer (part of 10),
20 current supply lead (part of 14),
22 top face (part of 10),
24 second electric heater (part of 10),
26 second electric heater lead (part of 24),
28 bottom heater (part of 10),
30 bottom face (part of 10),
32 electronic component,
34 molten solder lump,
36 lead (part of 32),
38 air gap,
40 work holder,
42 current feed thru (part of 40),
44 heat barrier (part of 40),
46 vibration inducer means,
48 enclosure chamber,
50 heat insulation wrapping,
52 inlet means (part of 48),
54 outlet means (part of 48),
56 supply of empty PCBwEEH,
58 solder paste printing station,
60 self-reflow station,
62 stack of PCBwEEH,
64 components placement station,
66 pick-and-place machine,
68 inert gas atmosphere (inside 66),
70 cooling station,
72 cooling gas stream,
74 controllable electric current source,
76 electronic components supply,
78 stack enclosure (for 62),
80 inert gas environs (inside 78),
82 alternate process path (when SSD-PCBs are used) and
84 air shield (used during repair operation).

### GLOSSARY OF ACRONYMS

All throughout the specification, the abstract, the appended claims and figures some or all of the following acronyms or abbreviations are used;
BGA (ball grid array packaging),
PCB (printed circuit board),
PCBwEEH (printed circuit board with embedded electric heater),
QFP (quad flat package),
SSD (solid solder deposit) and
SSD-PCB (solid solder deposit-printed circuit board).

### SUMMARY OF THE INVENTION

This invention discloses a novel PCB that incorporates an electric heater embedded into its dielectric substrate. The heater, in due time, becomes the exclusive source of heat required to attain a self-reflowing soldering process rather than utilizing reflow oven equipment as customarily done nowadays by the electronic assembly industry. Multiple electronic components are simultaneously soldered to said PCB face when the embedded electric heater is supplied with an adequate electric current.

Specifically this invention; (1) improves the quality of electronic assemblies because the casing of the electronic components being soldered are not heated and, (2) reduces the cost of soldering electronic assemblies because it requires fewer manufacturing equipment and consumes less energy when compared to the prior art. As a result, electronic products assembled around this novel PCB should become of better quality, more reliable and its overall manufacturing cost reduced.

### DESCRIPTION OF INVENTION

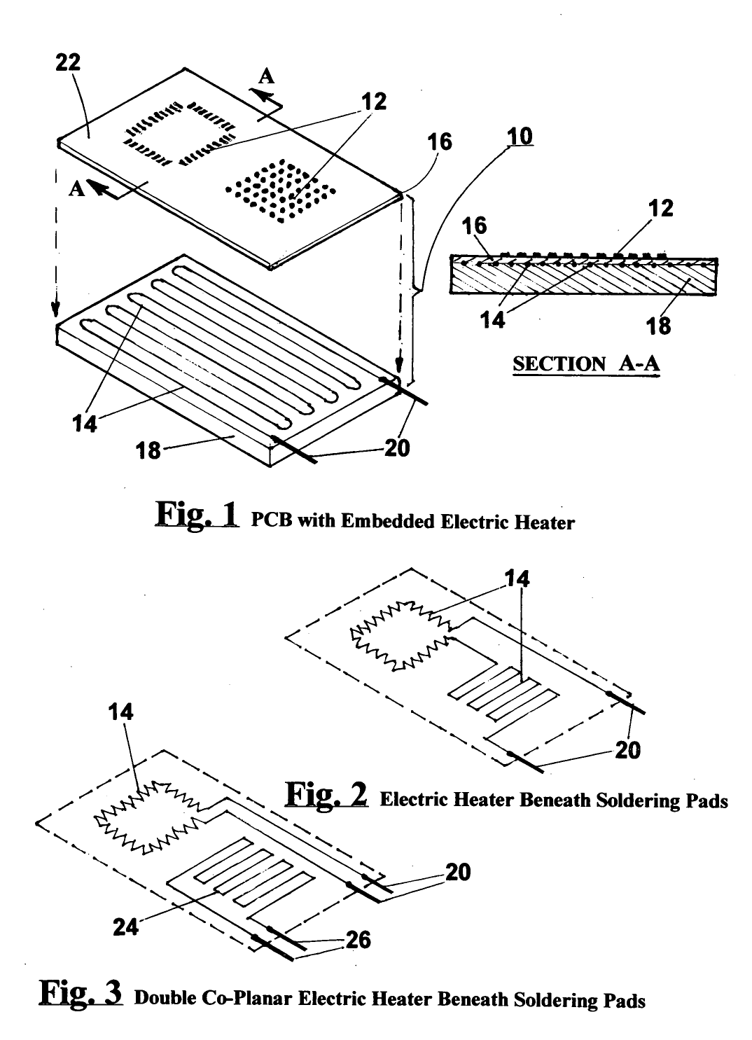

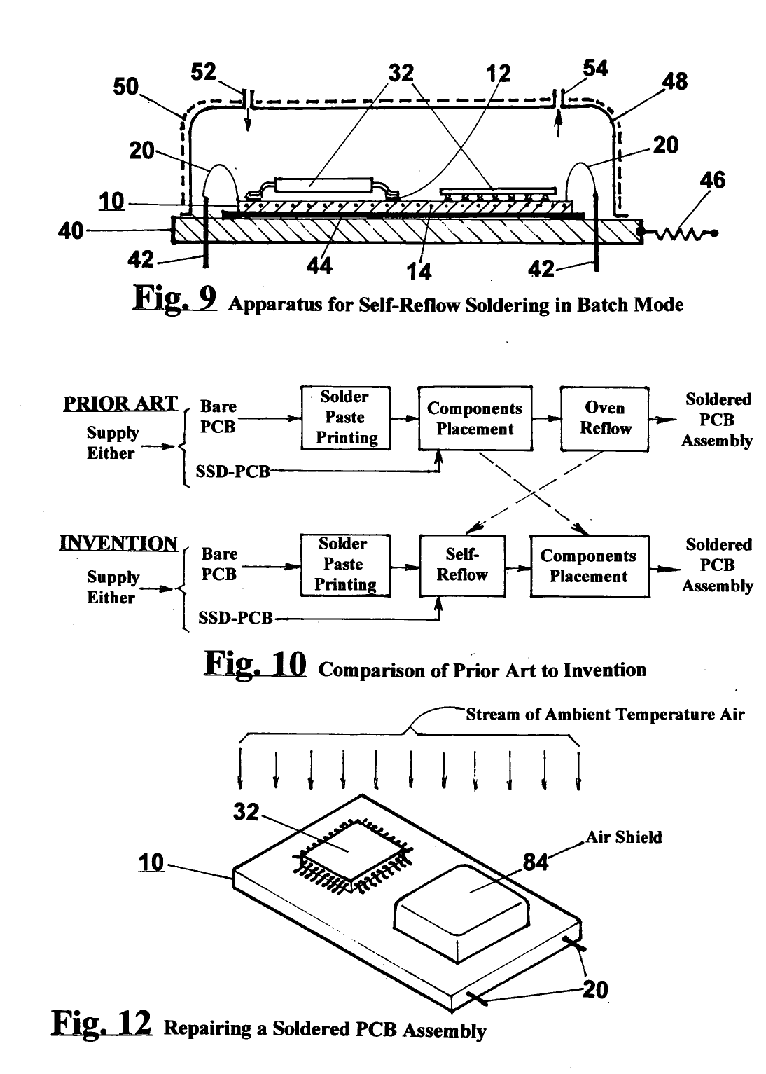

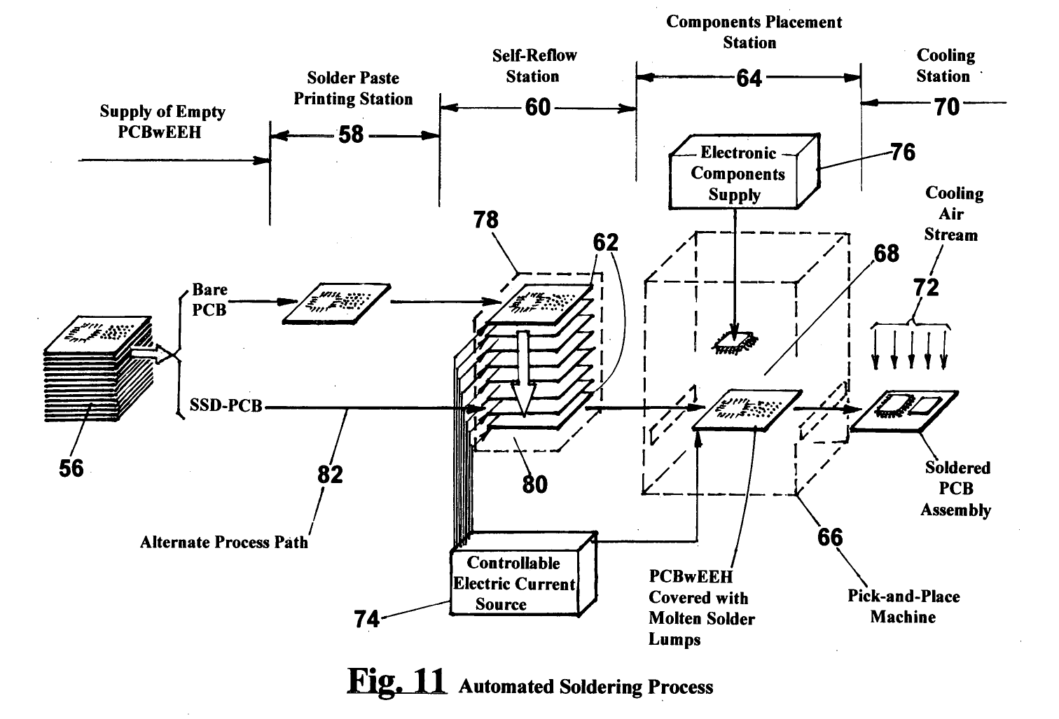

Now, aided by FIGS. 1 through 8, components that form part of the fundamental embodiment of this invention shall be illustrated and described. Because the additional embodiments that permit practical utilization of the fundamental embodiment of the invention also include items-of-commerce recognized as public-domain prior art, those preferred embodiments will be illustrated afterwards in FIG. 9 and FIG. 11 and described in the next part of this specification.

FIG. 1 shows in, both, exploded and sectional views the fundamental embodiment, namely a printed circuit board with embedded electric heater 10 (PCBwEEH 10) constructed according to this invention. To avoid clutter in the figure only two sets of soldering pads 12 are depicted, corresponding to the footprints of a QFP and a BGA packages. An electric heater 14 is embedded in a sandwich fashion between a top dielectric layer 16 and a bottom dielectric layer 18. Electric heater 14 has a pair of current supply leads 20-20 for supplying an electric current. Sectional view A-A depicts top dielectric layer 16 thinner than bottom dielectric layer 18 thus placing electric heater 14 close to said sets of soldering pads 12 in order to maximize heat transfer into pads 12. Electric heater 14 is uniformly stretched underneath the entire top face 22 in order to transfer relatively even heat into the whole top face 22.

Notice that the term—oven reflow soldering—refers to the customary process utilized by the prior art for obtaining soldered joints, consisting of baking a PCB assembly inside a reflow oven. The term—self-reflow soldering—refers to a process disclosed by this invention for obtaining soldered joints, consisting of supplying an electric current to a PCBwEEH instead of baking the PCBwEEH assembly inside a reflow oven.

In operation, during self-reflow soldering, an electric current of predetermined intensity is supplied to said leads 20-20 for a predetermined time duration in order to heat up said sets of soldering pads 12 to a predetermined temperature level sufficiently high to cause melting of any type of solder material (i.e. solder paste, SSD, flux-cored solid solder, dry solder powder, etc.) deposited on said sets of soldering pads 12. Said electric current is interrupted when it becomes necessary to allow solidification of said solder material in order to attain soldered joints.

Depending on the application it may be desirable that the heat transferred from heater 14 be directed, or concentrated, into predetermined areas of top face 22 as illustrated in FIG. 2 where, in operation, electric heater 14 only generates heat beneath the footprints of a QFP and a BGA components.

In other application it may be desirable to have embedded, on the same plane, two separate electric heaters as illustrated in FIG. 3 where, in operation, electric heaters 14 and 24 each is capable of only generating heat underneath corresponding soldering pads at different times and at different heating rates since each can be supplied with an independent current via their respective leads 20-20 and 26-26.

Still other application may require a single electric heater 14 capable of generating more intense heat underneath soldering pads and less intense heat over the remainder of the board as illustrated in FIG. 4 where dashed-lines represent less heat output.

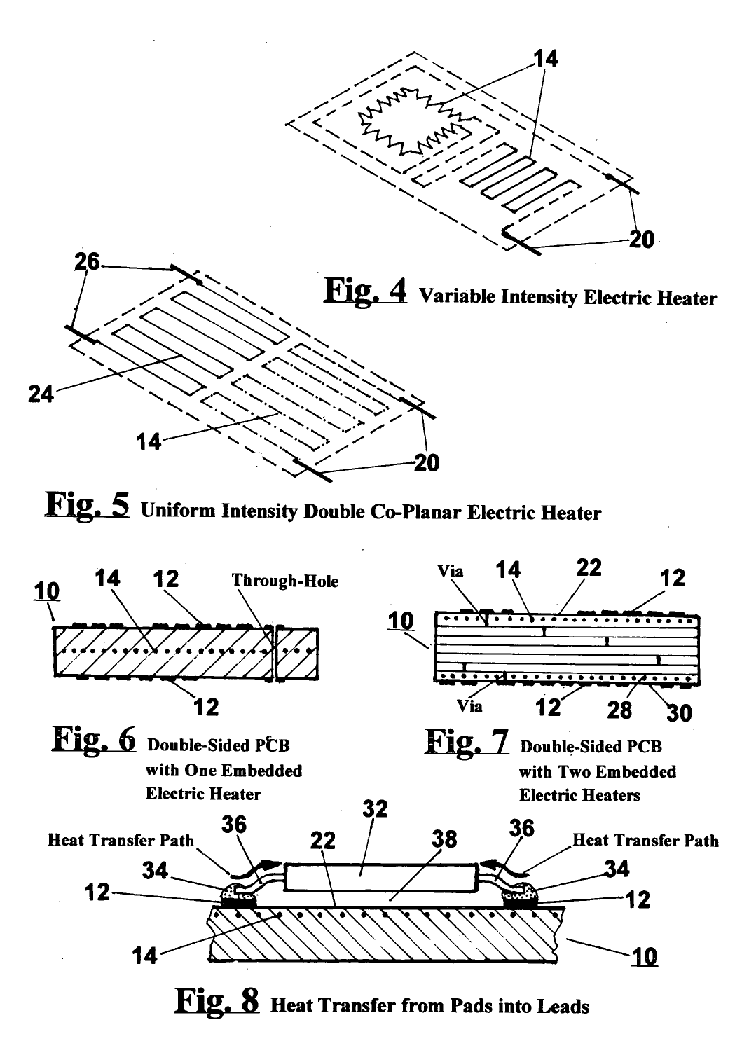

FIG. 5 shows a layout with two separate electric heaters 14 and 24 embedded on the same plane that, in operation, each generates uniform heating at different times and at different heating rates since each can be supplied with an independent current via their respective leads 20-20 and 26-26.

FIG. 1 through FIG. 5 illustrate the flexibility offered by this invention for internally heating a PCB substrate during self-reflow soldering. The prior art uses a reflow oven that can only supply, relatively uniform, external heat transfer all-round the PCB during oven reflow soldering operation.

Notice that leads 20-20 and 26-26 don't have to extend out of PCBwEEH 10 substrate as depicted in FIGS. 1 through 5. Indeed, said leads can be replaced by contact pads, connectors or current interfacing means affixed to a face of PCBwEEH 10.

Although FIG. 1 depicts a single-sided PCB, the invention is equally applicable to double-sided PCBs as illustrated in FIG. 6 and FIG. 7. Notice that in FIG. 7 in addition to the electric heater 14 placed adjacent to top face 22 a second separate electric heater 28 is place adjacent to bottom face 30. In operation, when electric current is only supplied to one of said heaters (because heaters 14 and 28 are farther apart from each other than are from their respective adjacent faces 22 and 30) a temperature gradient develops between faces 22 and 30. When face 22 is heated by heater 14 opposite face 30 reaches a lower temperature level than face 22.

This feature becomes useful when self-reflow soldering double-sided PCB assemblies populated by heavy components on both sides. First top face 22 is self-reflow soldered using heater 14 then the board is flipped, components are placed on bottom face 30 (now facing upward) and self-reflow soldered using heater 28. Notice that during operation when face 30 is being heated the temperature level on the opposite face 22 (now facing downward) is lower than the level required for soldered joints to remelt.

Notice that, although in the figures only surface mounted components are depicted, however, through-hole mounted components and straddle mounted components are equally soldered according to this invention.

From the above description the reader can appreciate the unobvious novelty disclosed, specifically the ability to eliminate the traditional reflow oven from a PCB soldering operation, a capital equipment cost reducing solution. With this invention PCB assemblies can be self-reflow soldered in an open-air environment. In addition, the invention offers other important advantages that are described below with the aid of FIG. 8.

When oven reflow soldering a PCB assembly according to the prior art the entire assembly is heated including the casing (and its internal parts) of every electronic component being soldered. Because of this harsh heating cycle components must be rated to survive reflow temperatures thus unnecessarily increasing their cost. However, as explained in the next paragraph, when applying this invention only the leads being soldered to a pad are heated.

Referring to FIG. 8, that shows in sectional view a portion of a single-sided PCBwEEH 10 with a component 32 being soldered to it. Notice that during self-reflow soldering a lump of molten solder 34 metallurgically attaches to, or wets, soldering pad 12 and lead 34 end point. Heat is first transferred, via conduction mechanism, from molten solder 34 into lead 36 end point and then from there to casing of component 32 (see arrows indicating heat transfer path). Because the rather short heating cycle, insignificant heat reaches the casing of component 32. Furthermore, heat transferred from hot top surface 22 into the casing of component 32 is negligible since it is transferred via convection through the air gap 38 existing between top surface 22 and underside of component 32.

### Description of Invention in Preferred Embodiment

Referring now specifically to the entirety of this invention, a simple embodiment intended for self-reflow soldering a PCB assembly is shown in FIG. 9 illustrated in accordance with the objectives of this invention by comprising a PCBwEEH 10 (itself comprising a multiplicity of upward facing solder pads 12 each covered with either a predetermined amount of solder paste or SSDs), an embedded electric heater 14 (itself including a pair of current supply leads 20-20), a plurality of electronic components 32 placed on top of said PCBwEEH 10, a workholder 40 (itself including a pair of current feed thru 42-42 and a heat barrier 44) where PCBwEEH 10 is resting and clamped down by clamping means not shown in the figure, means not shown to supply a predetermined electric current to supply leads 20-20 via feed thru 42-42, vibration inducer means 46 linked to said workholder 40, an enclosure chamber 48 (itself including heat insulation wrapping 50) that permits to contain vapors and/or gases generated during operation that may cause occupational health hazards and/or safety risks, means not shown to remove, in an environmentally safe manner, said vapor and/or gases, and controllable inlet means 52 and outlet means 54 for supplying an inert gas (such as Nitrogen, Argon, etc.) to said enclosure chamber 48.

In operation, a predetermined electric current is supplied to leads 20-20 via feed thru 42-42. The current heats up embedded electric heater 14 causing the solder paste, or if applicable the SSD, covering each soldering pad 12 to melt into individual lumps. Once every molten solder lump wets a pad 12 and the corresponding mating lead (or termination) that is part of electronic components 32 the electric current is interrupted to allow solder solidification to take place.

Concurrently, once the solder paste, or if applicable the SSD, covering each soldering pad 12 is melted, workholder 54 is made to vibrate under the action of vibration inducer means 46. The vibrations are transmitted from workholder 54 to every molten solder lump consequently; (1) facilitating the venting of any entrapped gas or vapor resulting from the heating of the solder paste and (2) enhancing the wetting action of molten solder upon pads 12 and leads. Venting produces void-free solder joints. The vibration is ceased after supplied current is interrupted. Identical results are attained if the vibrations are substituted by an ultrasound field generated inside enclosure chamber 48.

Subsequently enclosure 48 is removed allowing the soldered PCBwEEH 10 to cool down either naturally or by a forced flow of ambient air impinging on its upper surface. Subsequently soldered PCBwEEH 10 is removed from work holder 40 restoring the device for the next self-reflow soldering operation.

Before presenting the next embodiment it is useful to explain, with the aid of FIG. 10, the difference existing between the prior art and the next embodiment. In FIG. 10 the prior art approach for oven reflow soldering a PCB assemblies is compared against the approach of next embodiment. Notice the reversal in sequence between reflow and components placement steps as pointed out in the figure by arrow lines.

Notice that the term—self-reflow—refers to a process disclosed by this invention for attaining molten solder lumps on top of a PCBwEEH consisting of supplying and electric current to said PCBwEEH when its pads are covered with any type of solder material (i.e. solder paste, SSD, flux-cored solid solder, dry solder powder, etc.)

A third embodiment of this invention intended for automated self-reflow soldering PCB assemblies is shown in FIG. 11 illustrated in accordance with the objectives of this invention by comprising a supply of empty PCBwEEHs 56, a solder paste printing station 58, a self-reflow station 60 (itself comprising a stack of PCBwEEH 62), a components placement station 64 comprising an automated pick-and-place machine 66 (itself including and inert gas atmosphere 68), a cooling station 70 itself including a cooling gas stream 72, a controllable electric current source 74 and an electronic components supply 76.

In operation, one empty PCBwEEH (with its plurality of soldering pads facing upward) is sequentially furnished from the supply of empty PCBwEEH 56 to paste printing station 58 where an appropriate amount of solder paste is deposited over each soldering pad. The pasted PCBwEEH is then moved to self-reflow station 60 and placed at the top of stack 62, simultaneously from the bottom of the stack 62 an already self-reflowed PCBwEEH is moved into components placement station 64. As soon as a pasted PCBwEEH enters stack 62 it is supplied with a predetermined electric current from controllable electric current source 74. As the pasted PCBwEEH moves down the stack it is being continuously heated by said predetermined electric current which can be made variable in intensity as the stack moves down in order to attain a desirable heating rate of the solder paste. When a pasted PCBwEEH reaches the bottom of the stack all the solder paste has already melted forming a multiplicity of molten solder lumps covering said plurality of soldering pads facing upward.

One PCBwEEH with said multiplicity of molten solder lumps is moved from the bottom of stack 62 into components placement station 64 where pick-and-place machine 66 sequentially places electronic components in predetermined locations such as that their leads become in deep contact with a predetermined set of molten solder lumps. During components placement a predetermined current is once again supplied from controllable electric current source 74 to PCBwEEH in order to prevent premature solidification of said molten solder lumps. Once the last electronic component is placed the current is interrupted to allow solder solidification to take place thus forming soldered joints. Finally the soldered PCBwEEH assembly is moved to cooling station 70 where it is cooled down by said cooling gas stream 72 impinging on its face.

During continuous operation while one empty PCBwEEH is furnished from the supply of empty PCBwEEHs 56 a completed soldered assembly emerges at cooling station 70. In the process described above the pick-and-place machine 66 can be replaced by a manual method of placing electronic components without departing from the spirit and scope of this invention.

Stack 62 can be contained inside a stack enclosure 78 in order to prevent heat losses and to contain vapors and/or gases generated during operation that may cause occupational health hazards and/or safety risks. Stack enclosure 78 includes means not shown to remove, in an environmentally safe manner, said vapor and/or gases, and also includes controllable inlet means and outlet means not shown for supplying an inert gas environs 80 (such as Nitrogen, Argon, etc.) in order to prevent oxidation off said multiplicity of molten solder lumps covering said plurality of soldering pads facing upward. Similarly, the placement of components by pick-and-place machine 66 can be performed inside an inert gas atmosphere 68 to prevent oxidation of said multiplicity of molten solder lumps.

The number of pasted PCBwEEHs to be included into stack 62 can be approximately determined by dividing the self-reflow time required for properly achieving said multiplicity of molten solder lumps by the cycle-time utilized by automated pick-and-place machine 66 to place on a PCBwEEH all the electronic components required. The optimum self-reflow time required for forming molten solder lumps depends on the particular application and must be determined empirically, however, as a guide it should be assumed to be in the order of a few minutes. This rather long heating cycle is imposed by the need to prevent boiling of the flux contained into the solder paste, flux boiling results in paste splatter. On the other hand, the cycle-time utilized by automated pick-and-place machine 66 is in general a fraction of one minute. Consequently, stack 62 is required to avoid that pick-and-place machine 66 would have to stay idle, between components placement cycles, wastefully waiting for the arrival of a new board covered with a multiplicity of molten solder lumps.

Notice that—solid solder deposit (SSD)—refers to a relatively thick layer of solid solder metallurgically bonded over the soldering pads of a bare-PCB. Bare-PCB refers to a PCB that would require deposition of solder paste prior to components placements for a subsequent reflow soldering operation. And—solid solder deposit-printed circuit board (SSD-PCB)—refers to a PCB with its soldering pads covered by SSDs. Therefore, a SSD-PCB provides by itself, in solid form, adequate amounts of solder fused to its soldering pads for reflow soldering components on it.

When the supply of empty PCBwEEHs 56 consist of SSD-PCBs all their pads are already covered with a SSD. Therefore there is no need to deposit solder paste because the solder is provided in solid form fused to the pads. In this case the solder paste printing station 58 is bypassed, see in FIG. 11 alternate process path 82.

When a PCBwEEH of the SSD-PCB type is utilized (since there is not possibility for splatter), the optimum cycle-time required for forming a multiplicity of molten solder lumps could be about equal or even shorter than the cycle-time utilized by automated pick-and-place machine 66 to place all the electronic components required on a PCBwEEH. In this specific case it would not be necessary to include stack 62 into self-reflow station 60 since it will be possible to quickly heat only one board at the time.

Notice that after a soldered PCBwEEH is completed its embedded electric heater remains inside its substrate. Should, after testing the assembly for proper functionality it is detected a damaged electronic component or defective soldered joints, rework may be required. In this case the embedded electric heater becomes very useful for performing a safe repair operation.

The component to be re-soldered or removed is temporary covered with an air shield 84 as shown in FIG. 12, then a predetermined current is supplied to the embedded electric heater and simultaneously a stream of ambient temperature air is made to impinge the entire face of the already soldered PCBwEEH. The portion of soldered PCBwEEH not covered by air shield 84 will never reach a temperature level high enough to cause re-melting of already soldered joints because the heat transferred from embedded heater is constantly removed by said stream of ambient temperature air. However, the soldered joints of the component under air shield 84 will remelt. Then, (a) the defective component can be lifted up from the PCBwEEH for replacement or (b) allow the re-melted soldered joints to re-form by interrupting said predetermined current.

Repairing a PCB according to the prior art requires that the entire component to be removed or re-soldered be heated by a localized stream of hot air, a harsh process equivalent to oven reflow soldering. Therefore a PCBwEEH offers a harmless repair process.

### SUMMARY, RAMIFICATIONS, AND SCOPE OF INVENTION

Accordingly, the reader should notice that this invention is a truly innovative one that provides the electronic packaging industry with; (a) a new, safe and reliable PCBwEEH capable of self-reflow soldering operation and, (b) novel and useful processes for assembling electronic components.

Since the disclosed PCBwEEH and its associated processes do not require the cooperation of an external heat source, i.e. a reflow oven, as the prior art does, the utilization of this invention offers the following advantages when compared against the prior art:
spares the electronic components being soldered to a PCBwEEH from the harsh oven reflow process that prior art imposes because now only the leads being soldered are heated, consequently reducing rejects and reducing rework,
heat sensitive components, such as electrolytic capacitors (that in general are capable of surviving up to 120° C.), can simultaneously be soldered with other heat-hardy components because their casings are not heated,
eliminates the need to de-moisturize certain components, for example plastic BGAs, because their casings are not heated,
eliminates possibility of thermal shock due to a fast heating rate that can crack certain components such as ceramic capacitors because their casings are not heated,
reduces energy consumption with respect to the prior art because, (a) heat losses into the surroundings are much less than those resulting from operating a reflow oven and (b) the heat input absorbed by a PCBwEEH assembly during self-reflow is less than when utilizing oven reflow soldering since components casings are not heated,
reduces the cost of capital investment because a reflow oven is not needed to assemble PCBwEEHs,
reduces the required manufacturing floor space because the reflow oven is eliminated,
reduces the overall cost of manufacturing PCB assemblies because the savings enumerated above, and
allows to perform a harmless repair operation.

Although the above description contains many specificities, these should not be construed as limiting the scope of the invention but as merely providing illustrations of some of the presently preferred embodiments of this invention. Any compositions or methods which are functionally equivalent are within the scope of this invention. Indeed, from the forgoing description, various other variations and structural changes will become apparent to those skilled in the art without departing from the spirit and scope of this invention.

Accordingly, the scope of this invention should be determined by the appended claims and their legal equivalents, rather than by the embodiment illustrated.

I claim:

1. A single-sided PCBwEEH that incorporates within its dielectric substrate an embedded electric heater capable of generating the heat necessary to solder components on its top face, comprising:
(a) a dielectric substrate itself comprising a multiplicity of soldering pads on its top face, and
(b) an electric heater embedded within said dielectric substrate itself comprising a pair of current supply leads whereby when a predetermined electric current is supplied to said pair of current supply leads said multiplicity of soldering pads become heated to a predetermined temperature level.

2. A double-sided PCBwEEH that incorporates within its dielectric substrate an embedded electric heater capable of generating the heat necessary to simultaneously solder components on its top and bottom faces, comprising:
(a) a dielectric substrate itself comprising a multiplicity of soldering pads on its top face and a plurality of soldering pads on its bottom face, and
(b) an electric heater embedded within said dielectric substrate itself comprising a pair of current supply leads
whereby when a predetermined electric current is supplied to said pair of current supply leads said multiplicity of soldering pads and said plurality of soldering pads become simultaneously heated to a predetermined temperature level.

3. A double-sided PCBwEEH that incorporates within its dielectric substrate two embedded electric heaters each capable of generating the heat necessary to independently solder components on its top and bottom faces, comprising:
(a) a dielectric substrate itself comprising a multiplicity of soldering pads on its top face and a plurality of soldering pads on its bottom face, and
(b) a top electric heater embedded within said dielectric substrate adjacent to said top face itself comprising a pair of top current supply leads, and
(c) a bottom electric heater embedded within said dielectric substrate adjacent to said bottom face itself comprising a pair of bottom current supply leads
whereby when a predetermined electric current is supplied to either said pair of top current supply leads or to said pair of bottom current supply leads either said multiplicity of soldering pads or said plurality of soldering pads become individually heated to a predetermined temperature level.

4. A single-sided PCBwEEH that incorporates within its dielectric substrate an embedded electric heater capable of generating the heat necessary to solder components on its top face, comprising:
(a) a dielectric substrate itself comprising a multiplicity of soldering pads on its top face with each pad from said multiplicity of soldering pads covered with a SSD, and
(b) an electric heater embedded within said dielectric substrate itself comprising a pair of current supply leads
whereby when a predetermined electric current is supplied to said pair of current supply leads said multiplicity of soldering pads become heated to a predetermined temperature level causing melting of each of said SSDs.

5. A double-sided PCBwEEH that incorporates within its dielectric substrate an embedded electric heater capable of generating the heat necessary to simultaneously solder components on its top and bottom faces, comprising:
(a) a dielectric substrate itself comprising a multiplicity of soldering pads on its top face with each pad from said multiplicity of soldering pads covered with a SSD and a plurality of soldering pads on its bottom face also with each pad from said plurality of soldering pads covered with a SSD, and
(b) an electric heater embedded within said dielectric substrate itself comprising a pair of current supply leads
whereby when a predetermined electric current is supplied to said pair of current supply leads said multiplicity of soldering pads and said plurality of soldering pads become simultaneously heated to a predetermined temperature level causing melting of all of said SSDs.

6. A double-sided PCBwEEH that incorporates within its dielectric substrate two embedded electric heaters each capable of generating the heat necessary to independently solder components on its top and bottom faces, comprising:
(a) a dielectric substrate itself comprising a multiplicity of soldering pads on its top face with each pad from said multiplicity of soldering pads covered with a SSD and a plurality of soldering pads on its bottom face also with each pad from said plurality of soldering pads covered with a SSD, and
(b) a top electric heater embedded within said dielectric substrate adjacent to said top face itself comprising a pair of top current supply leads, and
(c) a bottom electric heater embedded within said dielectric substrate adjacent to said bottom face itself comprising a pair of bottom current supply leads
whereby when a predetermined electric current is supplied to either said pair of top current supply leads or to said pair of bottom current supply leads either said multiplicity of soldering pads or said plurality of soldering pads become individually heated to a predetermined temperature level causing melting of all of said SSDs covering the pads being heated.

7. An apparatus primarily intended for soldering electronic components to a PCBwEEH in batch mode, comprising:
(a) a PCBwEEH resting and clamped on top of a workholder said PCBwEEH itself comprising a dielectric substrate an electric heater embedded within said dielectric substrate itself comprising a pair of current supply leads a multiplicity of soldering pads on the face of said substrate facing upward a predetermined amount of solder paste volumes deposited on top of each pad from said multiplicity soldering pads, and
(b) a plurality of electronic components each of them comprising a plurality of soldering terminals placed on top of said predetermined amount of solder paste volumes in pre-decided locations, and
(c) means to supply a predetermined electric current to said pair of current supply leads for a predetermined time sufficiently long to first cause melting of said predetermined amount of solder paste volumes and subsequently to form soldered joints between said multiplicity of soldering pads and said plurality of soldering terminals
whereby in operation a finished PCBwEEH assembly is obtained.

8. The apparatus of claim 7, further comprising:
(d) an enclosure chamber
whereby the inclusion permits to contain gases or vapors generated during operation that may cause occupational health hazards and/or safety risks and permits to supply and inert gas atmosphere in order to prevent oxidation of molten solder.

9. The apparatus of claim 8, further comprising:
(e) means to shake said workholder
whereby the inclusion permits to induce vibrations into said predetermined amount of solder paste volumes during heating and melting hence enhancing both flux vapors venting and solder wetting.

10. An apparatus primarily intended for soldering electronic components to a PCBwEEH in batch mode, comprising:
(a) a PCBwEEH resting and clamped on top of a workholder said PCBwEEH itself comprising a dielectric substrate an electric heater embedded within said dielectric substrate itself comprising a pair of current supply leads a multiplicity of soldering pads on the face of said substrate facing upward with each pad from said multiplicity of soldering covered with a SSD, and
(b) a plurality of electronic components each of them comprising a plurality of soldering terminals placed on top of said SSDs in pre-decided locations, and
(c) means to supply a predetermined electric current to said pair of current supply leads for a predetermined time sufficiently long to first cause melting of said SSDs and subsequently to form soldered joints between said multiplicity of soldering pads and said plurality of soldering terminals
whereby in operation a finished PCBwEEH assembly is obtained.

11. The apparatus of claim 10, further comprising:
(d) an enclosure chamber
whereby the inclusion permits to supply and inert gas atmosphere in order to prevent oxidation of molten solder.

12. The apparatus of claim 11, further comprising:
(e) means to shake said workholder
whereby the inclusion permits to induce vibrations into molten solder hence enhancing solder wetting.

13. A manual process for soldering electronic components to a PCBwEEH, comprising the steps of:
(a) supplying a PCBwEEH itself comprising a dielectric substrate an electric heater embedded within said dielectric substrate itself comprising a pair of current supply leads a multiplicity of soldering pads on the face of said substrate facing upward, and
(b) depositing a predetermined amount of solder paste volumes on top of each of said multiplicity of soldering pads on the face of said substrate facing upward attaining a pasted PCBwEEH, and
(c) supplying a predetermined electric current to said pair of current supply leads for a predetermined time sufficiently long to cause melting of said predetermined amount of solder paste volumes on top of each of said multiplicity of soldering pads on a side facing upward in order to form a multiplicity of molten solder lumps on top of each of said multiplicity of soldering pads on a face facing upward attaining a PCBwEEH covered with molten solder lumps, and
(d) placing manually one by one electronic components themselves comprising a plurality of terminals on top of said multiplicity of molten solder lumps in predetermined locations such as that each terminal from said plurality of terminals is deepen into one of said molten solder lumps, and
(e) supplying a pre-planned electric current to said pair of current supply leads during step (d) in order maintain said molten solder lumps in liquidus state, and
(f) interrupting said pre-planned electric current once the last electronic component is placed on top of said multiplicity of molten solder lumps in order to initiate solidification of said multiplicity of molten solder lumps thus attaining a soldered PCBwEEH
whereby a finished PCB assembly is obtained.

14. The process of claim 13, further comprising the step of:
(g) placing said pasted PCBwEEH inside an enclosure during steps (c), (d) and (e)
whereby the inclusion permits to contain gases or vapors generated during operation that may cause occupational health hazards and/or safety risks and to supply and inert gas atmosphere in order to prevent oxidation of said multiplicity of molten solder lumps.

15. The process of claim 14, further comprising the step of:
(h) shaking said PCBwEEH covered with molten solder lumps during steps (c), (d) and (e)
whereby enhancing both flux vapors venting and solder wetting.

16. A manual process for soldering electronic components to a PCBwEEH, comprising the steps of:
(a) supplying a PCBwEEH itself comprising a dielectric substrate an electric heater embedded within said dielectric substrate itself comprising a pair of current supply leads a multiplicity of soldering pads on the face of said substrate facing upward with each pad from said multiplicity of soldering pads covered with a SSD, and
(b) supplying a predetermined electric current to said pair of current supply leads for a predetermined time sufficiently long to cause melting of said SSDs on top of each of said multiplicity of soldering pads on a side facing upward in order to form a multiplicity of molten solder lumps on top of each of said multiplicity of soldering pads on a face facing upward attaining a PCBwEEH covered with molten solder lumps, and
(c) placing manually one by one electronic components themselves comprising a plurality of terminals on top of said multiplicity of molten solder lumps in predetermined locations such as that each terminal from said plurality of terminals is deepen into one molten solder lump, and
(d) supplying a pre-planned electric current to said pair of current supply leads during step (c) in order maintain said molten solder lumps in liquidus state, and
(e) interrupting said pre-planned electric current once the last electronic component is placed on top of said multiplicity of molten solder lumps in order to initiate solidification of said multiplicity of molten solder lumps thus attaining a soldered PCBwEEH
whereby a finished PCB assembly is obtained.

17. The process of claim 16, further comprising the step of:
(f) placing said pasted PCBwEEH inside an enclosure during steps (b), (c) and (d)
whereby the inclusion permits to supply and inert gas atmosphere in order to prevent oxidation of said multiplicity of molten solder lumps.

18. The process of claim 17, further comprising the step of:
(g) shaking said PCBwEEH covered with molten solder lumps during steps (b), (c) and (d)
whereby enhancing solder wetting.

19. An automated process for soldering electronic components to a PCBwEEH, comprising the steps of:
(a) supplying a PCBwEEH itself comprising a dielectric substrate an electric heater embedded within said dielectric substrate itself comprising a pair of current supply leads a multiplicity of soldering pads on the face of said substrate facing upward, and
(b) depositing a predetermined amount of solder paste volumes on top of each of said multiplicity soldering pads attaining a pasted PCBwEEH, and
(c) placing said pasted PCBwEEH on top of a stack, and
(d) causing said stack to move downward carrying along said pasted PCBwEEH, and
(e) supplying while said stack moves downward a predetermined electric current to said pair of current supply leads for a predetermined time sufficiently long to cause melting of said predetermined amount of solder paste volumes on top of each of said multiplicity of soldering pads in order to form a multiplicity of molten solder lumps on top of each of said multiplicity of soldering pads as said pasted PCBwEEH reaches the bottom of said stack attaining a PCBwEEH covered with molten solder lumps, and
(f) transporting said PCBwEEH covered with molten solder lumps into a automated pick-and-place machine, and
(g) supplying a pre-planned electric current to said pair of current supply leads in order maintain said multiplicity of molten solder lumps in liquidus state, and
(h) causing said automated pick-and-place machine to sequentially place one by one electronic components themselves comprising a plurality of terminals on top of said multiplicity of molten solder lumps in predetermined locations such as that each terminal from said plurality of terminals is deepen into one molten solder lump, and
(i) interrupting said pre-planned electric current once the last electronic component is placed on top of said multiplicity of molten solder lumps in order to initiate solidification of said multiplicity of molten solder lumps thus attaining a soldered PCBwEEH, and
(j) transporting said soldered PCBwEEH out of said automated pick-and-place machine
whereby a finished PCB assembly is obtained.

20. The process of claim 19, further comprising the step of:
(k) placing said stack inside an enclosure whereby the inclusion permits during step (e) to contain gases or vapors generated during operation that may cause occupational health hazards and/or safety risks and to supply and inert gas atmosphere in order to prevent oxidation of said multiplicity of molten solder lumps.

21. The process of claim 20, further comprising the step of:
(l) performing steps (g) and (h) inside an inert gas atmosphere whereby the inclusion permits to prevent oxidation of said multiplicity of molten solder lumps.

22. The process of claim 21, further comprising the step of:
(m) shaking said PCBwEEH covered with said multiplicity of molten solder lumps during step (h) whereby enhancing solder wetting.

23. An automated process for soldering electronic components to a PCBwEEH, comprising the steps of:
(a) supplying a PCBwEEH itself comprising a dielectric substrate an electric heater embedded within said dielectric substrate itself comprising a pair of current supply leads a multiplicity of soldering pads on the face of said substrate facing upward with each pad from said multiplicity of soldering pads covered with a SSD, and
(b) placing said PCBwEEH on top of a stack, and
(c) causing said stack to move downward, and
(d) supplying while said stack moves downward a predetermined electric current to said pair of current supply leads for a predetermined time sufficiently long to cause melting of said SSDs in order to form a multiplicity of molten solder lumps on top of each of said multiplicity of soldering pads as said PCBwEEH reaches the bottom of said stack attaining a PCBwEEH covered with molten solder lumps, and
(e) transporting said PCBwEEH covered with molten solder lumps into a automated pick-and-place machine, and
(f) supplying a pre-planned electric current to said pair of current supply leads in order maintain said multiplicity of molten solder lumps in liquidus state, and
(g) causing said automated pick-and-place machine to sequentially place one by one electronic components themselves comprising a plurality of terminals on top of said multiplicity of molten solder lumps in predetermined locations such as that each terminal from said plurality of terminals is deepen into one molten solder lump, and
(h) interrupting said pre-planned electric current once the last electronic component is placed on top of said multiplicity of molten solder lumps in order to initiate solidification of said multiplicity of molten solder lumps thus attaining a soldered PCBwEEH, and
(i) transporting said soldered PCBwEEH out of said automated pick-and-place machine
whereby a finished PCB assembly is obtained.

24. The process of claim 23, further comprising the step of:
(j) placing said stack inside an enclosure
whereby the inclusion permits during step (d) to supply and inert gas atmosphere in order to prevent oxidation of said multiplicity of molten solder lumps.

25. The process of claim 24, further comprising the step of:
(k) performing steps (f) and (g) inside an inert gas atmosphere
whereby the inclusion permits to prevent oxidation of said multiplicity of molten solder lumps.

26. The process of claim 25, further comprising the step of:
(l) shaking said PCBwEEH covered with said multiplicity of molten solder lumps during step (g)
whereby enhancing solder wetting.
